(19) United States
(12) Patent Application Publication
(10) Pub. No.: US 2014/0124849 A1
(43) Pub. Date: May 8, 2014

(54) B4-FLASH DEVICE AND THE MANUFACTURING METHOD THEROF

(71) Applicant: Shanghai Huali Microelectronics Corporation, Shanghai (CN)

(72) Inventors: Zhi TIAN, Shanghai (CN); JingLun GU, Shanghai (CN)

(21) Appl. No.: 14/069,517

(22) Filed: Nov. 1, 2013

(30) Foreign Application Priority Data
Nov. 2, 2012 (CN) 201210432508.X

(51) Int. Cl. H01L 29/792; H01L 21/28

(52) U.S. Cl. CPC H01L 29/792; H01L 21/28282
USPC 257/324; 438/591

(57) ABSTRACT

The invention provides a B4-flash device and the manufacture method thereof, wherein the device comprises a substrate, a first silicon oxide layer, a silicon nitride layer and a second silicon oxide layer, and all those layers are disposed on the substrate in sequence. The first silicon oxide layer comprises a first section, a second section and a third section, and all those sections are along the channel direction in sequence. The thickness ratio among the first section, the second section and the third section is (1.5-2.5):(0.8-1.2):(1.5-2.5). The embodiments of the present invention use the non-uniform silicon oxide to slow down the degeneration of the silicon oxide and to relieve the effect of the programming of the electron injection and the erasing of the holes injection as well. As a result, the reliability of the device is improved.

### CROSS-REFERENCE TO RELATED APPLICATIONS

The present application claims priority under the Paris Convention to Chinese application number CN 201210432508.X, filed on Nov. 2, 2012, the disclosure of which is herewith incorporated by reference in its entirety.

### FIELD OF THE INVENTION

The present invention relates to a device and the manufacturing method thereof, and it particularly relates to a device which applies to B4 flash program and holes tunneling injection erasing and the method for manufacturing the device.

### BACKGROUND OF THE INVENTION

With regard to a NOR flash memory cell, the key point to limit the further reduction of the size is the decrease of the gate length. Because in the programming of channel hot electron (CHE) injection, it requires a certain voltage value to a drain electrode, and this voltage has a great influence on punch-through of the source and drain so that this programming is not suitable for the short channel devices. Another problem is that the outputted program of NOR flash are limited in comparison with the data memory devices such like the NAND and AND.

Recently, Shoji Shukuri et al. have proposed a novel P channel unit for utilizing back bias assisted band-to-band tunneling induced hot-electron injection (B4-flash) to conduct the programming (“60 nm NOR Flash Memory Cell Technology Utilizing Back Bias Assisted Band-to-Band Tunneling Induced Hot-Electron Injection (B4-Flash)”, 2006 Symposium on VLSI Technology Digest of Technical Papers). Wherein, this technology of programming by the back bias assisted and band-to-band tunneling is shown in FIG. 1. Firstly, the electric field formed by the voltage between gate and drain generates some band-to-band tunneling electrons 10. Then these tunneling electrons 10 get away from the drain by the effect of an electric field of drain charge space, which is formed by the voltage of substrate bias. Finally, the tunneling electrons 10 are injected into a charge storage layer with the assistance of the vertical electric field formed by the voltage of the substrate bias and the gate. Although the mentioned back bias assisted band-to-band P channel device has been reported previously, it still needs a higher drain voltage to get enough hot electrons for programming. And the overly high drain voltage will easily cause the punch-through in the channel. As a result, the length of gate is still limited (T. Ohnakado, et al., IEEE Trans. EL. Vol. 46. No. 9, 1999, pp. 1866-1870), and the size of the device is also limited to be further reduced.

Chinese patent (CN 102386187A) has disclosed a SONOS device. The gate of the device comprises a first layer of silicon oxide, a second layer of silicon nitride, a third layer of silicon oxide, and a fourth layer of polysilicon, and those layers according to the sequence from bottom to top. The thickness of the first layer is greater than the thickness of the third layer. In the above patent, the process of writing electrons is proceeded, by the CHE injection, and the electrons will pass through the first layer of silicon oxide.

### SUMMARY OF THE INVENTION

Due to the defects of the prior arts, the present invention discloses a method of using the non-uniform silicon oxide to slow down the degeneration of the silicon oxide and to relieve the effects of the partial electron injection and the erasing of the uniform holes injection. As a result, the reliability of the device is improved.

The invention provides a B4-flash device, wherein the device comprises a substrate and a first silicon oxide layer, a silicon nitride layer and a second silicon oxide layer, and all those layers are disposed on the substrate in sequence. The said first silicon oxide layer comprises a first section, a second section and a third section. All those Sections are along the channel direction in sequence. The thickness ratio among the first section, the second section and the third section is (1.5-2.5):(0.8-1.2):(1.5-2.5).

In a preferred aspect of the present invention, the thickness ratio among the first section, the second section and the third section is 2:1:2.

In a preferred aspect of the present invention, the length ratio among the first section, the second section and the third section is (0.8-1.2):(2.5-3.5):(0.8-1.2).

In a preferred aspect of the present invention, the length ratio among the first section, the second section and the third section is 1:3:1.

In a preferred aspect of the present invention, the thickness of the first section of the first silicon oxide layer ranges from 1 nm to 4 nm.

In a preferred aspect of the present invention, the thickness of the silicon nitride layer ranges from 5 nm to 20 nm.

In a preferred aspect of the present invention, the method comprises the following steps:

Step 1, a silicon oxide layer is formed on the substrate, then a first silicon oxide layer is formed by etching;

Step 2, a silicon nitride layer and a second silicon oxide layer are formed on the said first silicon oxide layer in sequence.

In a preferred aspect of the present invention, a Step 3 is also included, wherein the gate is formed by etching and ion implanting.

The advantages of the above technical solutions as follows:

The embodiments of the invention provide a non-uniform SONOS (Silicon-Oxide-Nitride-Oxide-Silicon) structure, wherein the different tunneling silicon oxide thickness induce the electric field intensities be different in different areas. There is a greater electric field intensity caused by the thinner thickness of the middle area of the silicon oxide layer. During the tunneling program of Fowler-Nordheim, more holes may pass through the area. As both sides of the channel are disposed with thicker tunneling silicon oxide layers, the electric field intensity is weaker and the incoming holes are less. As a result, the erasing rate is improved. Furthermore, the number of the holes in both sides is reduced by the circular process of programming and erasing so that the performance of the device is improved. It means the process is compatible with the CMOS and the costs may be saved.

### BRIEF DESCRIPTION OF THE DRAWINGS

FIG. 1 is a structure diagram of the devices in the prior art;

FIG. 2 is a curve diagram of the durability of the device in the prior art;

FIG. 3 is a structure diagram of an embodiment of the present invention;

FIG. 4 is a performance diagram of an embodiment of the present invention.

### DETAILED DESCRIPTION OF THE PREFERRED EMBODIMENT

The present invention will be further illustrated in combination with the figures.

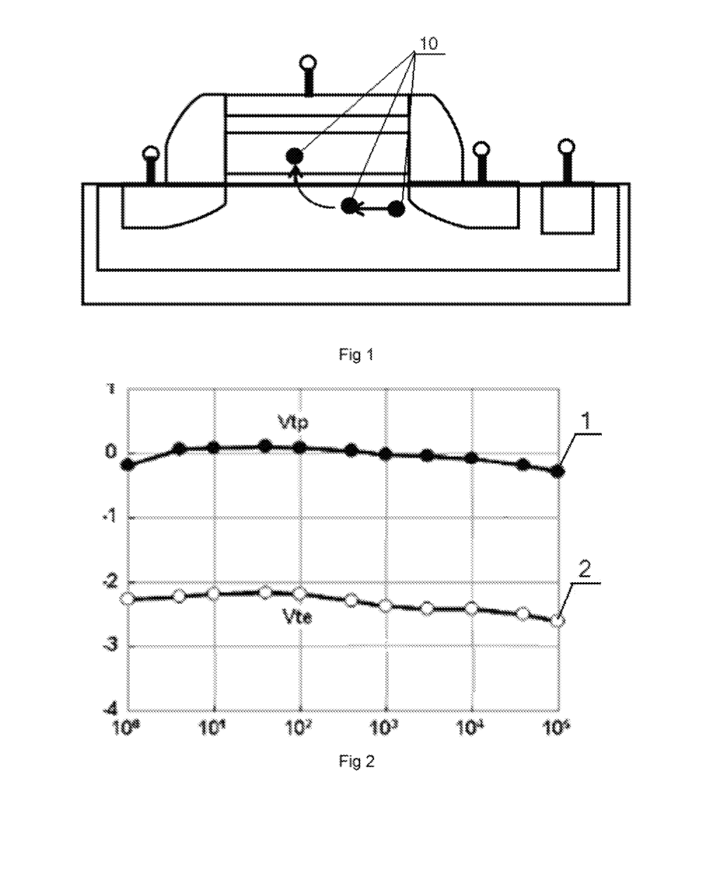

In the 60 nm SONOS structure of memory cell, the substrate bias is utilized to assist the band-to-band tunneling induced hot electron injection (also known as ‘Bulk Bias assisted Band to Band induced hot electron injection’) for programming operation for flash memory cells. Meanwhile, the Fowler-Nordheim holes tunneling (also named FN tunneling) injection is used for erasing. Therefore, a lot of advantages are achieved by this structure in comparison with other devices. The electrons and holes all affect the silicon oxide layer during the program/erase cycling, but both of the programming voltage and erasing voltage may still change periodically. As shown in FIG. 2, Line 1 and Line 2 indicate that the programming voltage Vtp and the erasing voltage Vte (indicated by the ordinate axis) are changed with the increasing of the number of program/erase cycles (indicated by the abscissa axis). As shown in the FIG. 2, the trend of the programming state and the trend of erasing state are decreased at the same time (actually, the required voltage should be increased to meet the practical demands). Since there is no obvious change in operating window, it means that the speed of programming did not drop substantially. In other words, the speed of the BTBT (Band-To-Band Tunneling) does not decrease substantially. But the situation that the programming voltage and the erasing voltage (absolute value) increase at the same time will cause the current be reduced, thus the read speed will be decreased. The electrons and holes can tunnel through the tunneling silicon oxide layer in the cycles of programming and erasing so that the electric charge will be neutralized in the tunneling silicon layer. As a result, the change of the threshold voltage, which is caused by the fixed electric charge in the tunneling silicon layer, will be very little. In the PMOS (P-channel Metal Oxide Semiconductor) transistor, the threshold voltage (absolute value) will be increased because the holes are accumulated in some place, thus the intensity of the corresponding electric field will be weakened so that the threshold voltage (absolute value) will be increased. It is because that the hot electrons of the bulk bias assisted BTBT are injected into the charge storage layer of the SONOS structure. As the electrons are injected into storage layer from certain points and the charge storage layer of the SONOS structure is a silicon nitride layer, the injected electrons are trapped by the traps of the silicon nitride layer. As a result, the injected electrons will congregate at the middle area of the charge storage layer. During the erasing operation stage, the Fowler-Nordheim tunneling holes injection is used for erasing, and this tunneling process is well-distributed. In other words, the holes are injected into storage layer from the entire channel. The injected electrons are limited to a region by the traps of SiN (silicon nitride) layer, and the region is near the injection point. Then the injected holes will neutralize the electrons, but there will be some other holes not combined with the electrons so that a part of the holes will be remain during the programming and erasing operation.

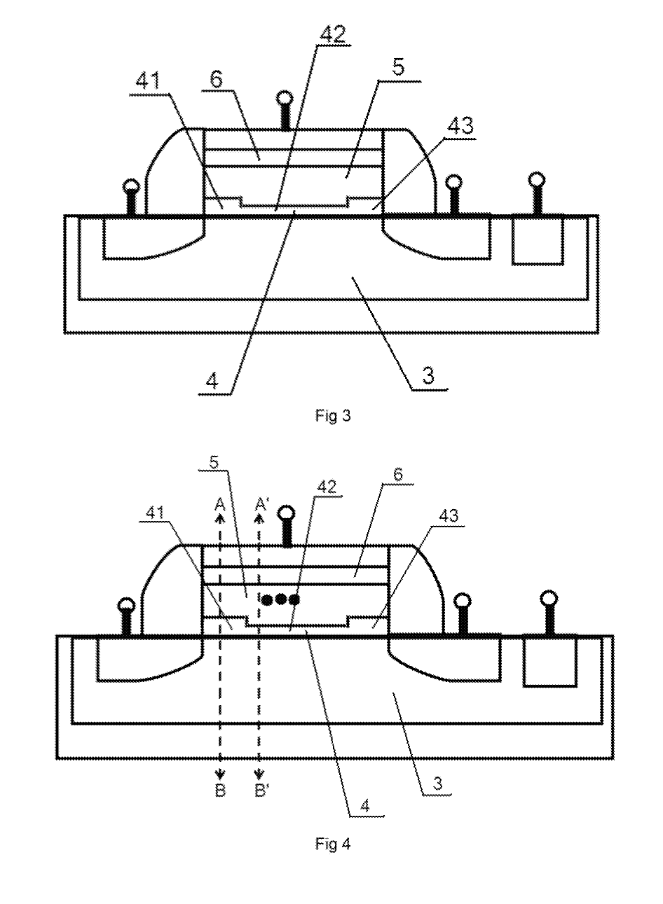

As shown in FIG. 3, there is an embodiment of the B4-flash device in the present invention. The device comprises a substrate 3 and a first layer of silicon oxide 4, the silicon nitride layer 5 and a second layer of silicon oxide 6, wherein all those layers are disposed on the substrate in sequence. The first layer of silicon oxide 4 comprises a first section 41, a second section 42 and a third section 43, and those sections are disposed along the channel direction in sequence. The thickness ratio among the first section 41, the second section 42 and the third section 43 is (1.5-2.5):(0.8-1.2):(1.5-2.5).

In the SONOS structure of an embodiment in the present invention, the tunneling silicon oxide layers of different thickness can have the different electric field intensity distribution. Thereby, more holes can be injected into the middle part of the tunneling silicon oxide by Fowler-Nordheim tunneling holes injection. The electrons are injected and stored in the middle area so that a higher erasing speed can be achieved. Both sides are consisted of the thicker tunneling silicon oxide layers so that the electric field intensity is weaker and the amount of the injected holes is less. Therefore, the possibility of the remaining holes in the cycles of programming and erasing is decreased. As a result, the increasing of the voltage (absolute value) of programming and erasing is limited due to the remaining holes. Moreover, the reading current of the device will be stabilized and the reliability of the device will be improved.

As shown in FIG. 4, in the operation of erasing by Fowler-Nordheim tunneling holes injection, under the effect of the gate negative voltage and the substrate positive voltage, the holes in the substrate 3 are moved into the charge storage layer, i.e., the silicon nitride layer 5. Because the middle area (also called the second section 42) is thinner, just as shown in the Cross-Section (A-B) of FIG. 4, there is a greater electric field intensity φh/d1 (φh means the barrier between the holes and the silicon oxide, d1 means the thickness of the tunneling silicon oxide) so that more holes will be combined with the injected electrons in the above area; because the two sides of the tunneling silicon oxide (also called the first section 41 and the third section 43) are thicker, just as shown in the Cross-Section (A′-B′) of FIG. 4, the corresponding electric field intensity φh/d2 is weaker (d2 is the thickness of the tunneling silicon oxide in the first section or the third section, d2>d1) so that there are less holes moved into the first section and the third section. In this way, during the cycles of programming and erasing, there will be many holes combined with electrons in the electrons area. Therefore, the number of the remaining holes is decreased so that the increasing of the threshold voltage (absolute value) will be limited. Besides, the threshold voltage is got after the cycle of programming and erasing, so the threshold voltage of programming and erasing is stabilized.

As shown in FIG. 3, there is an embodiment of the present invention, wherein it includes the following steps:

Step 1: a silicon oxide layer is formed on the substrate 3, then the first layer of silicon oxide 4 is formed through etching; the first layer of the silicon oxide comprises three sections: a first section, a second section and a third section; the preferred thickness ratio of the first section 41, the second section 42 and the third section 43 is 2:1:2, the preferred thickness of the second section 42 ranges from 1 nm to 4 nm. The length ratio of the first section, the second section and the third section is (0.8-1.2):(2.5-3.5):(0.8-1.2), and the preferred ratio 1:3:1;

Step 2: a silicon nitride layer 5 and a second silicon oxide layer 6 are formed on the first silicon oxide layer 4 in sequence; the preferred thickness of the silicon nitride layer 5 ranges from 5 nm to 20 nm, the silicon nitride layer can trap the injected electrons in the trap level in order to change the threshold voltage of programming and erasing; the second silicon oxide layer 6 is formed on the silicon nitride layer 5, and this silicon nitride layer 5 is used for storing the electrons. In this way, the effect of the gate charge injection in the storage layer will be prevented;

Step 3: a gate is formed by etching and ion implanting. The unessential ONO layer and polysilicon layer are removed by etching. Finally, the source and drain are formed by ion implanting.

It should be appreciated that the detailed descriptions about the preferred embodiments are only examples. They should not be deemed as limitation on this invention. It is obvious for the skilled in the art to make varieties of changes and modifications after reading the above descriptions. Hence, the Claims attached should be regarded as all the changes and modifications which cover the real intention and the range of this invention. Any and all equivalent contents and ranges in the range of the Claims should be regarded belonging to the intention and the range of this invention.

1. A B4-flash device, wherein the device comprises a substrate, a first silicon oxide layer, a silicon nitride layer and a second silicon oxide layer, and all those layers are disposed on the substrate in sequence; the said first silicon oxide layer comprises a first section, a second section and a third section, and all those sections are along the channel direction in sequence; the thickness ratio among the first section, the second section and the third section is (1.5-2.5):(0.8-1.2):(1.5-2.5).

2. The B4-flash device according to claim 1, wherein the thickness ratio among the first section, the second section and the third section is 2:1:2.

3. The B4-flash device according to claim 1, wherein the length ratio among the first section, the second section and the third section is (0.8-1.2):(2.5-3.5):(0.8-1.2).

4. The B4-flash device according to claim 3, wherein the length ratio among the first section, the second section and the third section is 1:3:1.

5. The B4-flash device according to claim 1, wherein the thickness of the first section of the first silicon oxide layer ranges from 1 nm to 4 nm.

6. The B4-flash device according to claim 2, wherein the thickness of the first section of the first silicon oxide layer ranges from 1 nm to 4 nm.

7. The B4-flash device according to claim 5, wherein the thickness of the silicon nitride layer ranges from 5 nm to 20 nm.

8. The B4-flash device according to claim 6, wherein the thickness of the silicon nitride layer ranges from 5 nm to 20 nm.

9. A method of manufacturing the B4-flash device according to claim 1, wherein the method comprises the following steps:
Step 1, a silicon oxide layer is formed on the substrate, then a first silicon oxide layer is formed by etching;
Step 2, a silicon nitride layer and a second silicon oxide layer are formed on the said first silicon oxide layer in sequence.

10. The method according to claim 1, wherein the method further comprises the following step:
Step 3: the gate is formed by etching and ion implanting.
